(19) United States
(12) Patent Application Publication
(10) Pub. No.: US 2014/0273451 A1
(43) Pub. Date: Sep. 18, 2014

(54) TUNGSTEN DEPOSITION SEQUENCE

(71) Applicant: Applied Materials, Inc., Santa Clara, CA (US)

(72) Inventors: Benjamin C. Wang, Santa Clara, CA (US); Amit Khandelwal, San Jose, CA (US); Avegerinos V. Gelatos, Redwood City, CA (US); Joshua Collins, Sunnyvale, CA (US); Kedar Sapre, San Jose, CA (US); Nitin K. Ingle, San Jose, CA (US)

(21) Appl. No.: 13/914,738

(22) Filed: Jun. 11, 2013

Related U.S. Application Data
(60) Provisional application No. 61/780,208, filed on Mar. 13, 2013.

(51) Int. Cl. H01L 21/285

(52) U.S. Cl. CPC H01L 21/28562
USPC 438/675

(57) ABSTRACT

Methods of filling gaps with tungsten are described. The methods include a tungsten dep-etch-dep sequence to enhance gapfilling yet avoid difficulty in restarting deposition after the intervening etch. The first tungsten deposition may have a nucleation layer or seeding layer to assist growth of the first tungsten deposition. Restarting deposition with a less-than-conductive nucleation layer would impact function of an integrated circuit, and therefore avoiding tungsten “poisoning” during the etch is desirable. The etching step may be performed using a plasma to excite a halogen-containing precursor while the substrate at relatively low temperature (near room temperature or less). The plasma may be local or remote. Another method may be used in combination or separately and involves the introduction of a source of oxygen into the plasma in combination with the halogen-containing precursor.

### CROSS-REFERENCES TO RELATED APPLICATIONS

This application claims the benefit of U.S. Prov. Pat. App. No. 61/780,208 filed Mar. 13, 2013, and titled “TUNGSTEN DEPOSITION SEQUENCE,” which is hereby incorporated herein in its entirety by reference for all purposes.

### STATEMENT AS TO RIGHTS TO INVENTIONS MADE UNDER FEDERALLY SPONSORED RESEARCH AND DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

Semiconductor device geometries have dramatically decreased in size since their introduction several decades ago. Modern semiconductor fabrication equipment routinely produce devices with 32 nm, 28 nm, and 22 nm feature sizes, and new equipment is being developed and implemented to make devices with even smaller geometries. The decreasing feature sizes result in structural features on the device having decreased spatial dimensions. The widths of gaps and trenches on the device narrow to a point where the aspect ratio of gap depth to its width becomes high enough to make it challenging to fill the gap with material. The depositing material is prone to clog at the top before the gap completely fills, producing a void or seam in the middle of the gap.

The gapfill deposition of tungsten films using chemical vapor deposition (CVD) techniques is an integral part of many semiconductor fabrication processes. Tungsten films may be used as low resistivity electrical connections in the form of horizontal interconnects, vias between adjacent metal layers, and contacts between a first metal layer and the devices on the silicon substrate. In a conventional tungsten deposition process, the wafer is heated to the process temperature in a vacuum chamber a tungsten film (the bulk layer) is deposited on a nucleation layer. Conventionally, the tungsten bulk layer is formed by the reduction of tungsten hexafluoride (WF₆) with hydrogen (H₂) on the growing tungsten layer. Trenches may promote the formation of trapped pockets within the gapfill tungsten despite the conformal nature of the CVD bulk layer tungsten deposition.

Methods are needed to selectively and delicately etch exposed metal surfaces.

### BRIEF SUMMARY OF THE INVENTION

Methods of filling gaps with tungsten are described. The methods include a tungsten dep-etch-dep sequence to enhance gapfilling yet avoid difficulty in restarting deposition after the intervening etch. The first tungsten deposition may have a nucleation layer or seeding layer to assist growth of the first tungsten deposition. Restarting deposition with a less-than-conductive nucleation layer would impact function of an integrated circuit, and therefore avoiding tungsten “poisoning” during the etch is desirable. The etching step may be performed using a plasma to excite a halogen-containing precursor while the substrate at relatively low temperature (near room temperature or less). The plasma may be local or remote. Another method may be used in combination or separately and involves the introduction of a source of oxygen into the plasma in combination with the halogen-containing precursor.

Embodiments of the invention include methods of depositing tungsten in a trench on a patterned substrate. The methods include the sequential steps of (i) depositing a first tungsten layer in the trench, (ii) partially etching the first tungsten layer from the trench, and (iii) depositing a second tungsten layer to fill the trench. The step of partially etching the tungsten from the trench occurs while the patterned substrate is in a substrate processing region of a substrate processing chamber. Partially etching the tungsten includes flowing a fluorine-containing precursor into a remote plasma region fluidly coupled to the substrate processing region while forming a plasma in the remote plasma region to produce plasma effluents. Partially etching the first tungsten layer further includes partially etching the first tungsten layer from the patterned substrate by flowing the plasma effluents into the substrate processing region. A temperature of the substrate is below or about 40° C. during the step of partially etching the first tungsten layer.

Embodiments of the invention include methods of depositing tungsten in a trench on a patterned substrate. The methods include the sequential steps of (i) depositing a first tungsten layer in the trench, (ii) partially etching the first tungsten layer from the trench, and (iii) depositing a second tungsten layer to fill the trench. The step of partially etching the tungsten from the trench occurs while the patterned substrate is in a substrate processing region of a substrate processing chamber. Partially etching the tungsten includes flowing a fluorine-containing precursor and oxygen (O₂) into a remote plasma region fluidly coupled to the substrate processing region while forming a plasma in the remote plasma region to produce plasma effluents. Partially etching the first tungsten layer further includes partially etching the first tungsten layer from the patterned substrate by flowing the plasma effluents into the substrate processing region.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### BRIEF DESCRIPTION OF THE DRAWINGS

A further understanding of the nature and advantages of the disclosed embodiments may be realized by reference to the remaining portions of the specification and the drawings.

FIG. 1 is a flow chart of a tungsten gapfill process according to disclosed embodiments.

FIG. 2 is a flow chart of a tungsten gapfill process according to disclosed embodiments.

FIG. 3A shows a schematic cross-sectional view of a substrate processing chamber according to the disclosed technology.

FIG. 3B shows a schematic cross-sectional view of a portion of a substrate processing chamber according to the disclosed technology.

FIG. 3C shows a bottom plan view of a showerhead according to the disclosed technology.

FIG. 4 shows a top plan view of an exemplary substrate processing system according to the disclosed technology.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF THE INVENTION

Methods of filling gaps with tungsten are described. The methods include a tungsten dep-etch-dep sequence to enhance gapfilling yet avoid difficulty in restarting deposition after the intervening etch. The first tungsten deposition may have a nucleation layer or seeding layer to assist growth of the first tungsten deposition. Restarting deposition with a less-than-conductive nucleation layer would impact function of an integrated circuit, and therefore avoiding tungsten “poisoning” during the etch is desirable. The etching step may be performed using a plasma to excite a halogen-containing precursor while the substrate at relatively low temperature (near room temperature or less). The plasma may be local or remote. Another method may be used in combination or separately and involves the introduction of a source of oxygen into the plasma in combination with the halogen-containing precursor.

The inventors have found new ways to deposit tungsten into trenches (e.g. contact holes or vias) in a patterned substrate. A first tungsten layer may be deposited by chemical vapor deposition using a variety of conventional means. The “bulk” deposition may be carried out by thermal chemical vapor deposition at elevated substrate temperature using tungsten hexafluoride and hydrogen (H₂). The deposition of the first tungsten layer may be preceded by formation of a nucleation layer to facilitate growth of the first tungsten layer. The first tungsten layer is etched in a specific manner to avoid “poisoning” the etched first tungsten layer. A poisoned first tungsten layer has been found to hinder the deposition of the second tungsten layer, which would require an additional nucleation layer in order to restart growth for the second tungsten layer. The additional nucleation layer would reside within the gapfill tungsten material and would reduce the overall tungsten gapfill conductivity. The methods described herein avoid inclusion of this additional nucleation layer. The second tungsten layer may simply be restarted without the additional nucleation layer and is deposited directly on the partially etched first tungsten layer by conventional tungsten “bulk” chemical vapor deposition means.

An ion suppression element may be included in the etch processes discussed herein which occur between deposition of the first and second tungsten layers. The ion suppression element functions to reduce or eliminate ionically charged species traveling from the plasma generation region to the substrate. Uncharged neutral and radical species may pass through the openings in the ion suppressor to react at the substrate. The ion suppressor helps control the concentration of ionic species in the reaction region at a level that assists the process.

In accordance with some embodiments of the invention, an ion suppressor as described in the exemplary equipment section may be used to provide radical and/or neutral species for selectively etching substrates. In one embodiment, for example, an ion suppressor is used to provide fluorine-containing plasma effluents to selectively etch tungsten. The ion suppressor may be used to provide a reactive gas having a higher concentration of radicals than ions. Because most of the charged particles of a plasma are filtered or removed by the ion suppressor, the substrate is not necessarily biased during the etch process. Such a process using radicals and other neutral species can reduce plasma damage compared to conventional plasma etch processes that include sputtering and bombardment. Embodiments of the present invention are also advantageous over conventional wet etch processes where surface tension of liquids can cause bending and peeling of small features.

In order to better understand and appreciate the invention, reference is now made to FIG. 1 which is a flow chart of a tungsten gapfill process according to disclosed embodiments. A layer may be deposited prior to the steps shown in the figure, in order to increase growth rate or make growth of the bulk tungsten possible. The growth enabling layer may be referred to as an initiation layer or a nucleation layer. The nucleation layer may be grown by alternating exposure to differing precursors. A patterned substrate having a trench may be exposed to silane (SiH₄) and then exposed to tungsten hexafluoride (WF₆). The nucleation layer may include multiple applications of the alternating exposure. Diborane (B₂H₆) is another precursor which may be alternated with tungsten hexafluoride to produce a functional nucleation layer. Silane and diborane have higher sticking coefficients on a variety of non-tungsten surfaces and have been found to transition to high growth rate tungsten CVD.

Bulk gapfill chemical vapor deposition tungsten is deposited into the trench on the patterned substrate (operation 110). The deposition may be effected by a variety of conventional methods such as by thermal chemical vapor deposition using both tungsten hexafluoride and hydrogen (H₂). The substrate temperature may be greater than 200° C., greater than 250° C. or greater than 300° C. in disclosed embodiments. For example, the substrate temperature may be between 250° C. and 800° C. or between 300° C. and 400° C. The CVD substrate processing region may be plasma-free during the deposition. A variety of other tungsten precursors and reducing precursors may also be used during this first bulk gapfill chemical vapor deposition to form the first tungsten layer in the trench. The first tungsten layer may pinch together near the mouth of the trench to trap a small volume unfilled with tungsten. Alternatively, the first tungsten layer may narrow but not entirely pinch together. The narrowing may occur near the mouth of the trench and is narrower than the tungsten separation present deeper within the trench. These effects have been found to be more of a problem for narrower trenches. The trench width may be less than or about 30 nm, less than or about 25 nm, less than or about 20 nm or less than or about 15 nm in embodiments of the invention.

As a consequence of the narrowing or pinching together of the tungsten near the mouth of the trench, the first tungsten layer is partially etched back in order to regain some or additional access to the unfilled region within the trench. The etch process may be conducted in a separate substrate processing chamber from the substrate processing chamber used for the ensuing etch. Substrate processing regions described herein refer to the region containing the substrate during the etch process. The tungsten etch is initiated when a flow of nitrogen trifluoride is introduced into a remote plasma region separate from the substrate processing region (operation 120). Other sources of fluorine may be used to augment or replace the nitrogen trifluoride. In general, a fluorine-containing precursor may be flowed into the plasma region and the fluorine-containing precursor comprises at least one precursor selected from the group consisting of atomic fluorine, diatomic fluorine, bromine trifluoride, chlorine trifluoride, nitrogen trifluoride, hydrogen fluoride, sulfur hexafluoride, carbon tetrafluoride and xenon difluoride.

The inventors have observed higher etch rates for all embodiments disclosed herein when using sulfur hexafluoride in the mix of precursors delivered to the remote plasma region. However, sulfur hexafluoride was observed to poison the tungsten surface more readily than the other precursors tested, resulting in an increased tendency to slow the growth rate of the second tungsten layer. The inventors have further found that including nitrogen trifluoride in the mix of precursors delivered to the remote plasma region results in a lower etch rate than sulfur hexafluoride but a desirably reduced tendency to poison the etched tungsten surface. Carbon tetrafluoride also displayed particular utility for the tungsten gapfill applications described herein.

The separate plasma region may be referred to as a remote plasma region herein and may be within a distinct module from the processing chamber or a compartment within the processing chamber. The plasma effluents formed in the remote plasma region are then flowed into the substrate processing region (operation 125). The first tungsten layer partially filling the trench on the patterned substrate is etched (operation 130) such that tungsten is removed to regain access or provide additional access to the void or restricted space within the trench. The reactive chemical species and any process effluents are removed from the substrate processing region and then a second tungsten layer is deposited on the etched first tungsten layer (operation 135). The second tungsten layer may be deposited using conventional bulk deposition methods such as thermal chemical vapor deposition using tungsten hexafluoride and hydrogen as outlined previously. The deposition of the second tungsten layer may be deposited in a separate processing chamber.

FIG. 2 is a second flow chart of a tungsten gapfill process according to disclosed embodiments. A nucleation layer may be grown by alternating exposure to differing precursors as before. Bulk gapfill chemical vapor deposition tungsten is again deposited into the trench on the patterned substrate (operation 210). The deposition involves the same conventional means described previously with reference to FIG. 1. As before, the first tungsten layer may pinch together near the mouth of the trench to trap a small volume unfilled with tungsten or it may only partially pinch together without contact between adjacent asperities. The narrowing may occur near the mouth of the trench and is narrower than the tungsten separation present deeper within the trench. These effects have been found to be more of a problem for narrower trenches whose dimension ranges were recited previously.

The first tungsten layer is partially etched back in order to regain some or additional access to the unfilled region within the trench. The tungsten etch is initiated when a flow of nitrogen trifluoride and a flow of molecular oxygen (O₂) introduced into the remote plasma region separate from the substrate processing region (operation 220). The flow rate of the molecular oxygen may be between about 20% and about 100% of the flow rate of the nitrogen trifluoride in disclosed embodiments. The molecular oxygen and the nitrogen trifluoride may be combined prior to introduction into the remote plasma region or the pair of precursors may first mix within the remote plasma region in embodiments of the invention. Other sources of fluorine may be used to augment or replace the nitrogen trifluoride and suitable options were given previously with respect to FIG. 1.

The plasma effluents formed in the remote plasma region are then flowed into the substrate processing region (operation 225). The first tungsten layer partially filling the trench on the patterned substrate is etched (operation 230) such that tungsten is removed to regain access or additional access to the void or restricted space within the trench. The reactive chemical species and any process effluents are removed from the substrate processing region and the substrate may be transferred to a tungsten CVD chamber without exposing the patterned substrate to the atmosphere. A second tungsten layer is then deposited on the etched first tungsten layer (operation 235). The second tungsten layer may then completely fill or at least more significantly fill the trench with tungsten.

The sequences of steps represented in each of FIG. 1 and FIG. 2 may be succinctly described as dep-etch-dep sequences. More generally, dep-etch-dep-etch-dep sequences and dep-etch-dep-etch-dep-etch-dep sequences are also possible. The first tungsten layer and the second tungsten layer may be any adjacent dep steps represented in these extended sequences. For example, the first tungsten layer may be deposited on the substrate itself and the second tungsten layer may end up not entirely filling the trench in the substrate. A third or fourth tungsten layer may then be used in an extended sequence to fill the trench. Alternatively, the first tungsten layer may be deposited on a previously deposited tungsten layer and the second tungsten layer may fill the trench.

The flow of the fluorine-containing precursor may further include one or more relatively inert gases such as He, N₂, Ar. The inert gas can be used to improve plasma stability, process uniformity and the like. Argon is helpful, as an additive, to promote the formation of a stable plasma. Process uniformity is generally increased when helium is included. These additives are present in embodiments throughout this specification. Flow rates and ratios of the different gases may be used to control etch rates and etch selectivity.

In disclosed embodiments, the fluorine-containing gas (e.g. NF₃) is supplied at a flow rate of between about 5 sccm (standard cubic centimeters per minute) and 400 sccm, He at a flow rate of between about 0 slm (standard liters per minute) and 3 slm, and Ar at a flow rate of between about 0 slm and 3 slm. When oxygen is used, molecular oxygen (O₂) may be flowed at a flow rate between 5 sccm and 400 sccm. The flow rate of the molecular oxygen may be between about 20% and about 100% of the flow rate of the fluorine-containing precursor. One of ordinary skill in the art would recognize that other gases and/or flows may be used depending on a number of factors including processing chamber configuration, substrate size, geometry and layout of features being etched, and the like.

The method also includes applying energy to the fluorine-containing precursor while in the remote plasma region to generate the plasma effluents. As would be appreciated by one of ordinary skill in the art, the plasma may include a number of charged and neutral species including radicals and ions. The plasma may be generated using known techniques (e.g., radio frequency excitations, capacitively-coupled power, inductively coupled power, and the like). In an embodiment, the energy is applied using a capacitively-coupled plasma unit. The remote plasma source power may be between about 40 watts and about 5000 watts, between about 75 watts and about 2000 watts, between about 150 watts and about 1000 watts, or between about 200 watts and about 800 watts in embodiments of the invention. The pressure in the remote plasma region may be such that the pressure in the substrate processing region ends up between about 0.01 Torr and about 50 Torr or between about 0.1 Torr and about 5 Torr in disclosed embodiments. The capacitively-coupled plasma unit may be disposed remote from a gas reaction region of the processing chamber. For example, the capacitively-coupled plasma unit and the plasma generation region may be separated from the gas reaction region by a showerhead.

The temperature of the substrate may be lower during the partial etching according to embodiments represented in FIG. 1 than for embodiments represented in FIG. 2. The substrate temperature during the etch operations described herein may be between about −30° C. and about 400° C. in general, however, lower temperatures result in improved growth rates of the second tungsten layer (reduced “poisoning”). The substrate temperatures during etch processes disclosed herein may be less than or about 100° C., less than or about 70° C., less than or about 50° C., less than or about 30° C., less than or about 28° C., less than or about 25° C. or less than or about 20° C. in disclosed embodiments. Including the flow of molecular oxygen inhibits poisoning the surface of the etched first tungsten layer. When molecular oxygen is included in the process, the substrate temperatures during etch processes disclosed herein may be less than or about less than or about 40° C. less than or about 35° C., less than or about 30° C., less than or about 28° C., less than or about 25° C. or less than or about 20° C. in embodiments of the invention.

The pressure in the reaction region used to deposit tungsten by chemical vapor deposition (e.g. thermal CVD) generally determines the growth rate of the bulk tungsten layers discussed herein, namely the first tungsten layer and the second tungsten layer. The reaction region contains the patterned substrate and the precursors (e.g. WF₆ and H₂). The pressure in the reaction region may be greater than 10 Torr, greater than 50 Torr, greater than 100 Torr, greater than 200 Torr or greater than 300 Torr in disclosed embodiments. Upper limits are generally imposed by equipment and/or safety precautions.

Ranges for the dimensions of the trench filled with tungsten using the methods disclosed herein were given previously. The sidewalls of the trench may be a variety of dielectric materials. The sidewalls may have exposed materials which are homogeneous or heterogeneous and may include one or more of silicon, silicon nitride, silicon oxide, tungsten oxide, tungsten nitride, titanium oxide, titanium nitride or the like.

Additional process parameters are disclosed in the course of describing an exemplary processing chamber and system.

### Exemplary Processing System

FIG. 3A shows a cross-sectional view of an exemplary substrate processing chamber 1001 with partitioned plasma generation regions within the processing chamber. During film etching, e.g., titanium nitride, tantalum nitride, tungsten, silicon, polysilicon, silicon oxide, silicon nitride, silicon oxynitride, silicon oxycarbide, etc., a process gas may be flowed into chamber plasma region 1015 through a gas inlet assembly 1005. A remote plasma system (RPS) 1002 may optionally be included in the system, and may process a first gas which then travels through gas inlet assembly 1005. The inlet assembly 1005 may include two or more distinct gas supply channels where the second channel (not shown) may bypass the RPS 1002, if included. Accordingly, in disclosed embodiments the precursor gases may be delivered to the processing chamber in an unexcited state. In another example, the first channel provided through the RPS may be used for the process gas and the second channel bypassing the RPS may be used for a treatment gas in disclosed embodiments. The process gas may be excited within the RPS 1002 prior to entering the chamber plasma region 1015. Accordingly, the fluorine-containing precursor as discussed above, for example, may pass through RPS 1002 or bypass the RPS unit in disclosed embodiments. Various other examples encompassed by this arrangement will be similarly understood.

A cooling plate 1003, faceplate 1017, ion suppressor 1023, showerhead 1025, and a substrate support 1065 (also known as a pedestal), having a substrate 1055 disposed thereon, are shown and may each be included according to disclosed embodiments. The pedestal 1065 may have a heat exchange channel through which a heat exchange fluid flows to control the temperature of the substrate. This configuration may allow the substrate 1055 temperature to be cooled or heated to maintain relatively low temperatures, such as between about −20° C. to about 200° C., or therebetween. The heat exchange fluid may comprise ethylene glycol and/or water. The wafer support platter of the pedestal 1065, which may comprise aluminum, ceramic, or a combination thereof, may also be resistively heated in order to achieve relatively high temperatures, such as from up to or about 100° C. to above or about 1100° C., using an embedded resistive heater element. The heating element may be formed within the pedestal as one or more loops, and an outer portion of the heater element may run adjacent to a perimeter of the support platter, while an inner portion runs on the path of a concentric circle having a smaller radius. The wiring to the heater element may pass through the stem of the pedestal 1065, which may be further configured to rotate.

The faceplate 1017 may be pyramidal, conical, or of another similar structure with a narrow top portion expanding to a wide bottom portion. The faceplate 1017 may additionally be flat as shown and include a plurality of through-channels used to distribute process gases. Plasma generating gases and/or plasma excited species, depending on use of the RPS 1002, may pass through a plurality of holes, shown in FIG. 3B, in faceplate 1017 for a more uniform delivery into the chamber plasma region 1015.

Exemplary configurations may include having the gas inlet assembly 1005 open into a gas supply region 1058 partitioned from the chamber plasma region 1015 by faceplate 1017 so that the gases/species flow through the holes in the faceplate 1017 into the chamber plasma region 1015. Structural and operational features may be selected to prevent significant backflow of plasma from the chamber plasma region 1015 back into the supply region 1058, gas inlet assembly 1005, and fluid supply system 1010. The structural features may include the selection of dimensions and cross-sectional geometries of the apertures in faceplate 1017 to deactivate back-streaming plasma. The operational features may include maintaining a pressure difference between the gas supply region 1058 and chamber plasma region 1015 that maintains a unidirectional flow of plasma through the showerhead 1025. The faceplate 1017, or a conductive top portion of the chamber, and showerhead 1025 are shown with an insulating ring 1020 located between the features, which allows an AC potential to be applied to the faceplate 1017 relative to showerhead 1025 and/or ion suppressor 1023. The insulating ring 1020 may be positioned between the faceplate 1017 and the showerhead 1025 and/or ion suppressor 1023 enabling a capacitively coupled plasma (CCP) to be formed in the first plasma region. A baffle (not shown) may additionally be located in the chamber plasma region 1015, or otherwise coupled with gas inlet assembly 1005, to affect the flow of fluid into the region through gas inlet assembly 1005.

The ion suppressor 1023 may comprise a plate or other geometry that defines a plurality of apertures throughout the structure that are configured to suppress the migration of ionically-charged species out of chamber plasma region 1015 while allowing uncharged neutral or radical species to pass through the ion suppressor 1023 into an activated gas delivery region between the suppressor and the showerhead. In disclosed embodiments, the ion suppressor 1023 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 1023 may provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., W:WOx etch ratios, W:SiN etch ratios, etc.

The plurality of holes in the ion suppressor 1023 may be configured to control the passage of the activated gas, i.e., the ionic, radical, and/or neutral species, through the ion suppressor 1023. For example, the aspect ratio of the holes, or the hole diameter to length, and/or the geometry of the holes may be controlled so that the flow of ionically-charged species in the activated gas passing through the ion suppressor 1023 is reduced. The holes in the ion suppressor 1023 may include a tapered portion that faces chamber plasma region 1015, and a cylindrical portion that faces the showerhead 1025. The cylindrical portion may be shaped and dimensioned to control the flow of ionic species passing to the showerhead 1025. An adjustable electrical bias may also be applied to the ion suppressor 1023 as an additional means to control the flow of ionic species through the suppressor.

The ion suppression element 1023 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate is not always the desired goal. In many instances, ionic species are required to reach the substrate in order to perform the etch and/or deposition process. In these instances, the ion suppressor may help to control the concentration of ionic species in the reaction region at a level that assists the process.

Showerhead 1025 in combination with ion suppressor 1023 may allow a plasma present in chamber plasma region 1015 to avoid directly exciting gases in substrate processing region 1033, while still allowing excited species to travel from chamber plasma region 1015 into substrate processing region 1033. In this way, the chamber may be configured to prevent the plasma from contacting a substrate 1055 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if the exposed second material is oxide, this material may be further protected by maintaining the plasma remotely from the substrate.

The processing system may further include a power supply 1040 electrically coupled with the processing chamber to provide electric power to the faceplate 1017, ion suppressor 1023, showerhead 1025, and/or pedestal 1065 to generate a plasma in the chamber plasma region 1015 or processing region 1033. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to chamber plasma region 1015. This in turn may allow development of particular plasma characteristics such that precursors may be dissociated in specific ways to enhance the etching profiles produced by these precursors.

A plasma may be ignited either in chamber plasma region 1015 above showerhead 1025 or substrate processing region 1033 below showerhead 1025. A plasma may be present in chamber plasma region 1015 to produce the radical-fluorine precursors from an inflow of the fluorine-containing precursor. An AC voltage typically in the radio frequency (RF) range may be applied between the conductive top portion of the processing chamber, such as faceplate 1017, and showerhead 1025 and/or ion suppressor 1023 to ignite a plasma in chamber plasma region 1015 during deposition. An RF power supply may generate a high RF frequency of 13.56 MHz but may also generate other frequencies alone or in combination with the 13.56 MHz frequency.

Plasma power can be of a variety of frequencies or a combination of multiple frequencies. In the exemplary processing system the plasma may be provided by RF power delivered to faceplate 1017 relative to ion suppressor 1023 and/or showerhead 1025. The RF power may be between about 10 watts and about 5000 watts, between about 100 watts and about 2000 watts, between about 200 watts and about 1500 watts, or between about 200 watts and about 1000 watts in disclosed embodiments. The RF frequency applied in the exemplary processing system may be low RF frequencies less than about 200 kHz, high RF frequencies between about 10 MHz and about 15 MHz, or microwave frequencies greater than or about 1 GHz in different embodiments. The plasma power may be capacitively-coupled (CCP) or inductively-coupled (ICP) into the remote plasma region.

Chamber plasma region 1015 (top plasma in figure) may be left at low or no power when a bottom plasma in the substrate processing region 1033 is turned on to, for example, cure a film or clean the interior surfaces bordering substrate processing region 1033. A plasma in substrate processing region 1033 may be ignited by applying an AC voltage between showerhead 1055 and the pedestal 1065 or bottom of the chamber. A cleaning gas may be introduced into substrate processing region 1033 while the plasma is present.

A fluid, such as a precursor, for example a fluorine-containing precursor, may be flowed into the processing region 1033 by embodiments of the showerhead described herein. Excited species derived from the process gas in chamber plasma region 1015 may travel through apertures in the ion suppressor 1023, and/or showerhead 1025 and react with an additional precursor flowing into the processing region 1033 from a separate portion of the showerhead. Alternatively, if all precursor species are being excited in chamber plasma region 1015, no additional precursors may be flowed through the separate portion of the showerhead. Little or no plasma may be present in the processing region 1033. Excited derivatives of the precursors may combine in the region above the substrate and, on occasion, on the substrate to etch structures or remove species on the substrate in disclosed applications.

Exciting the fluids in the chamber plasma region 1015 directly, or exciting the fluids in the RPS units 1002, may provide several benefits. The concentration of the excited species derived from the fluids may be increased within the processing region 1033 due to the plasma in the chamber plasma region 1015. This increase may result from the location of the plasma in the chamber plasma region 1015. The processing region 1033 may be located closer to the chamber plasma region 1015 than the remote plasma system (RPS) 1002, leaving less time for the excited species to leave excited states through collisions with other gas molecules, walls of the chamber, and surfaces of the showerhead.

The uniformity of the concentration of the excited species derived from the process gas may also be increased within the processing region 1033. This may result from the shape of the chamber plasma region 1015, which may be more similar to the shape of the processing region 1033. Excited species created in the RPS 1002 may travel greater distances in order to pass through apertures near the edges of the showerhead 1025 relative to species that pass through apertures near the center of the showerhead 1025. The greater distance may result in a reduced excitation of the excited species and, for example, may result in a slower growth rate near the edge of a substrate. Exciting the fluids in the chamber plasma region 1015 may mitigate this variation for the fluid flowed through RPS 1002, or alternatively bypassed around the RPS unit.

The processing gases may be excited in chamber plasma region 1015 and may be passed through the showerhead 1025 to the processing region 1033 in the excited state. While a plasma may be generated in the processing region 1033, a plasma may alternatively not be generated in the processing region. In one example, the only excitation of the processing gas or precursors may be from exciting the processing gases in chamber plasma region 1015 to react with one another in the processing region 1033. As previously discussed, this may be to protect the structures patterned on the substrate 1055.

In addition to the fluid precursors, there may be other gases introduced at varied times for varied purposes, including carrier gases to aid delivery. A treatment gas may be introduced to remove unwanted species from the chamber walls, the substrate, the deposited film and/or the film during deposition. A treatment gas may be excited in a plasma and then used to reduce or remove residual content inside the chamber. In other disclosed embodiments the treatment gas may be used without a plasma. When the treatment gas includes water vapor, the delivery may be achieved using a mass flow meter (MFM), an injection valve, or by commercially available water vapor generators. The treatment gas may be introduced to the processing region 1033, either through the RPS unit or bypassing the RPS unit, and may further be excited in the first plasma region.

FIG. 3B shows a detailed view of the features affecting the processing gas distribution through faceplate 1017. As shown in FIG. 3A and FIG. 3B, faceplate 1017, cooling plate 1003, and gas inlet assembly 1005 intersect to define a gas supply region 1058 into which process gases may be delivered from gas inlet 1005. The gases may fill the gas supply region 1058 and flow to chamber plasma region 1015 through apertures 1059 in faceplate 1017. The apertures 1059 may be configured to direct flow in a substantially unidirectional manner such that process gases may flow into processing region 1033, but may be partially or fully prevented from backflow into the gas supply region 1058 after traversing the faceplate 1017.

The gas distribution assemblies such as showerhead 1025 for use in the processing chamber section 1001 may be referred to as dual channel showerheads (DCSH) and are additionally detailed in the embodiments described in FIG. 3A as well as FIG. 3C herein. The dual channel showerhead may provide for etching processes that allow for separation of etchants outside of the processing region 1033 to provide limited interaction with chamber components and each other prior to being delivered into the processing region.

The showerhead 1025 may comprise an upper plate 1014 and a lower plate 1016. The plates may be coupled with one another to define a volume 1018 between the plates. The coupling of the plates may be so as to provide first fluid channels 1019 through the upper and lower plates, and second fluid channels 1021 through the lower plate 1016. The formed channels may be configured to provide fluid access from the volume 1018 through the lower plate 1016 via second fluid channels 1021 alone, and the first fluid channels 1019 may be fluidly isolated from the volume 1018 between the plates and the second fluid channels 1021. The volume 1018 may be fluidly accessible through a side of the gas distribution assembly 1025. Although the exemplary system of FIGS. 3A-3C includes a dual-channel showerhead, it is understood that alternative distribution assemblies may be utilized that maintain first and second precursors fluidly isolated prior to the processing region 1033. For example, a perforated plate and tubes underneath the plate may be utilized, although other configurations may operate with reduced efficiency or not provide as uniform processing as the dual-channel showerhead as described.

In the embodiment shown, showerhead 1025 may distribute via first fluid channels 1019 process gases which contain plasma effluents upon excitation by a plasma in chamber plasma region 1015. In embodiments, the process gas introduced into the RPS 1002 and/or chamber plasma region 1015 may contain fluorine, e.g., CF₄, NF₃ or XeF₂. The process gas may also include a carrier gas such as helium, argon, nitrogen (N₂), etc. Plasma effluents may include ionized or neutral derivatives of the process gas and may also be referred to herein as a radical-fluorine precursor referring to the atomic constituent of the process gas introduced.

FIG. 3C is a bottom view of a showerhead 1025 for use with a processing chamber according to disclosed embodiments. Showerhead 1025 corresponds with the showerhead shown in FIG. 3A. Through-holes 231, which show a view of first fluid channels 1019, may have a plurality of shapes and configurations in order to control and affect the flow of precursors through the showerhead 1025. Small holes 227, which show a view of second fluid channels 1021, may be distributed substantially evenly over the surface of the showerhead, even amongst the through-holes 231, which may help to provide more even mixing of the precursors as they exit the showerhead than other configurations.

An additional dual channel showerhead, as well as this processing system and chamber, are more fully described in patent application Ser. No. 13/251,714 filed on Oct. 3, 2011, which is hereby incorporated by reference for all purposes to the extent not inconsistent with the claimed features and description herein.

The chamber plasma region 1015 or a region in an RPS may be referred to as a remote plasma region. In embodiments, the radical precursor, e.g., a radical-fluorine precursor, is created in the remote plasma region and travels into the substrate processing region where it may or may not combine with additional precursors. In embodiments, the additional precursors are excited only by the radical-fluorine precursor. Plasma power may essentially be applied only to the remote plasma region in embodiments to ensure that the radical-fluorine precursor provides the dominant excitation. Nitrogen trifluoride or another fluorine-containing precursor may be flowed into chamber plasma region 1015 at rates between about 5 sccm and about 500 sccm, between about 10 sccm and about 150 sccm, or between about 25 sccm and about 125 sccm in disclosed embodiments. Molecular oxygen (O₂) may be flowed with a flowrate between 20% and 100% of the flow rate of the fluorine-containing precursor.

Combined flow rates of precursors into the chamber may account for 0.05% to about 20% by volume of the overall gas mixture; the remainder being carrier gases. The fluorine-containing precursor may be flowed into the remote plasma region, but the plasma effluents may have the same volumetric flow ratio in embodiments. In the case of the fluorine-containing precursor, a purge or carrier gas may be first initiated into the remote plasma region before the fluorine-containing gas to stabilize the pressure within the remote plasma region.

Substrate processing region 1033 can be maintained at a variety of pressures during the flow of precursors, any carrier gases, and plasma effluents into substrate processing region 1033. The pressure may be maintained between about 0.1 mTorr and about 100 Torr, between about 1 Torr and about 20 Torr or between about 1 Torr and about 5 Torr in different embodiments.

Embodiments of the deposition systems may be incorporated into larger fabrication systems for producing integrated circuit chips. FIG. 4 shows one such processing system 1101 of deposition, etching, baking, and curing chambers according to disclosed embodiments. In the figure, a pair of front opening unified pods (load lock chambers 1102) supply substrates of a variety of sizes that are received by robotic arms 1104 and placed into a low pressure holding area 1106 before being placed into one of the substrate processing chambers 1108a-f. A second robotic arm 1110 may be used to transport the substrate wafers from the holding area 1106 to the substrate processing chambers 1108a-f and back. Each substrate processing chamber 1108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 1108a-f may include one or more system components for depositing, annealing, curing and/or etching a dielectric film on the substrate wafer. In one configuration, two pairs of the processing chamber, e.g., 1108c-d and 1108e-f, may be used to deposit dielectric material on the substrate, and the third pair of processing chambers, e.g., 1108a-b, may be used to etch the deposited dielectric. In another configuration, all three pairs of chambers, e.g., 1108a-f, may be configured to etch a dielectric film on the substrate. Any one or more of the processes described may be carried out in chamber(s) separated from the fabrication system shown in different embodiments.

In the preceding description, for the purposes of explanation, numerous details have been set forth in order to provide an understanding of various embodiments of the present invention. It will be apparent to one skilled in the art, however, that certain embodiments may be practiced without some of these details, or with additional details.

As used herein “substrate” may be a support substrate with or without layers formed thereon. The patterned substrate may be an insulator or a semiconductor of a variety of doping concentrations and profiles and may, for example, be a semiconductor substrate of the type used in the manufacture of integrated circuits. Exposed “silicon” of the patterned substrate is predominantly Si but may include minority concentrations of other elemental constituents such as nitrogen, oxygen, hydrogen, carbon and the like. Exposed “tungsten” of the patterned substrate is predominantly W but may include minority concentrations of other elemental constituents such as nitrogen, oxygen, hydrogen, carbon and the like. Of course, “exposed tungsten” may consist of only tungsten. Exposed “silicon nitride” of the patterned substrate is predominantly Si₃N₄ but may include minority concentrations of other elemental constituents such as oxygen, hydrogen, carbon and the like. “Exposed silicon nitride” may consist only of silicon and nitrogen. Exposed “silicon oxide” of the patterned substrate is predominantly SiO₂ but may include minority concentrations of other elemental constituents such as nitrogen, hydrogen, carbon and the like. In some embodiments, silicon oxide films etched using the methods disclosed herein consist of silicon and oxygen. “Tungsten oxide” is predominantly tungsten and oxygen but may include minority concentrations of other elemental constituents such as nitrogen, hydrogen, carbon and the like. Tungsten oxide may consist of tungsten and oxygen. “Titanium nitride” is predominantly titanium and nitrogen but may include minority concentrations of other elemental constituents such as nitrogen, hydrogen, carbon and the like. Titanium nitride may consist of titanium and nitrogen.

The term “precursor” is used to refer to any process gas which takes part in a reaction to either remove material from or deposit material onto a surface. “Plasma effluents” describe gas exiting from the chamber plasma region and entering the substrate processing region. Plasma effluents are in an “excited state” wherein at least some of the gas molecules are in vibrationally-excited, dissociated and/or ionized states. A “radical precursor” is used to describe plasma effluents (a gas in an excited state which is exiting a plasma) which participate in a reaction to either remove material from or deposit material on a surface. “Radical-fluorine” (or “radical-oxygen”) are radical precursors which contain fluorine (or oxygen) but may contain other elemental constituents. The phrase “inert gas” refers to any gas which does not form chemical bonds when etching or being incorporated into a film. Exemplary inert gases include noble gases but may include other gases so long as no chemical bonds are formed when (typically) trace amounts are trapped in a film.

The terms “gap” and “trench” are used throughout with no implication that the etched geometry has a large horizontal aspect ratio. Viewed from above the surface, trenches may appear circular, oval, polygonal, rectangular, or a variety of other shapes. A trench may be in the shape of a moat around an island of material. The term “via” is used to refer to a low aspect ratio trench (as viewed from above) which may or may not be filled with metal to form a vertical electrical connection. As used herein, a conformal etch process refers to a generally uniform removal of material on a surface in the same shape as the surface, i.e., the surface of the etched layer and the pre-etch surface are generally parallel. A person having ordinary skill in the art will recognize that the etched interface likely cannot be 100% conformal and thus the term “generally” allows for acceptable tolerances.

Having disclosed several embodiments, it will be recognized by those of skill in the art that various modifications, alternative constructions, and equivalents may be used without departing from the spirit of the disclosed embodiments. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of depositing tungsten in a trench on a patterned substrate, the method comprising the sequential steps:
(i) depositing a first tungsten layer in the trench,
(ii) partially etching the first tungsten layer from the trench, and
(iii) depositing a second tungsten layer;
wherein the step of partially etching the tungsten from the trench occurs while the patterned substrate is in a substrate processing region of a substrate processing chamber, and partially etching the tungsten comprises:
flowing a fluorine-containing precursor into a remote plasma region fluidly coupled to the substrate processing region while forming a plasma in the remote plasma region to produce plasma effluents, and partially etching the first tungsten layer from the patterned substrate by flowing the plasma effluents into the substrate processing region, wherein a temperature of the substrate is below or about 40° C. during the step of partially etching the first tungsten layer.

2. The method of claim 1 further comprising flowing oxygen (O₂) into the remote plasma region during the step of partially etching the first tungsten layer.

3. The method of claim 1 further comprising an additional step of (iv) partially etching the second tungsten layer and (v) depositing a third tungsten layer.

4. The method of claim 1 wherein the operation of (iii) depositing the second tungsten layer fills the trench.

5. The method of claim 1 wherein a temperature of the substrate is below or about 30° C. during the step of partially etching the first tungsten layer.

6. The method of claim 1 wherein the fluorine-containing precursor comprises at least one of nitrogen trifluoride, carbon tetrafluoride or sulfur hexafluoride.

7. The method of claim 1 wherein depositing the second tungsten layer comprises depositing tungsten by chemical vapor deposition from tungsten hexafluoride and hydrogen (H₂) at a patterned substrate temperature in excess of 200° C.

8. The method of claim 1 wherein the remote plasma region exists within the substrate processing chamber and is separated from the substrate processing region by a showerhead.

9. The method of claim 1 wherein a pressure within the substrate processing region is between about 0.01 Torr and about 50 Torr during the partial etching step.

10. The method of claim 1 wherein forming a plasma in the remote plasma region to produce plasma effluents comprises applying RF power between about 40 watts and about 5000 watts to the remote plasma region.

11. The method of claim 1 wherein the plasma effluents pass through an ion suppressor before entering the substrate processing region.

12. A method of depositing tungsten in a trench on a patterned substrate, the method comprising the sequential steps:
(i) depositing a first tungsten layer in the trench,
(ii) partially etching the first tungsten layer from the trench, and
(iii) depositing a second tungsten layer to fill the trench;
wherein the step of partially etching the tungsten from the trench occurs while the patterned substrate is in a substrate processing region of a substrate processing chamber, and partially etching the tungsten comprises:
flowing a fluorine-containing precursor and oxygen (O₂) into a remote plasma region fluidly coupled to the substrate processing region while forming a plasma in the remote plasma region to produce plasma effluents, and partially etching the first tungsten layer from the patterned substrate by flowing the plasma effluents into the substrate processing region.

13. The method of claim 12 wherein a temperature of the substrate is below or about 40° C. during the step of partially etching the first tungsten layer.

14. The method of claim 12 wherein a flow rate of the oxygen into the remote plasma region is between about 20% and about 100% of a flow rate of the fluorine-containing precursor.

15. The method of claim 12 wherein the first tungsten layer and the second tungsten layer consist of tungsten.

16. The method of claim 12 wherein the fluorine-containing precursor comprises at least one of atomic fluorine, diatomic fluorine, bromine trifluoride, chlorine trifluoride, nitrogen trifluoride, hydrogen fluoride, sulfur hexafluoride, carbon tetrafluoride and xenon difluoride.

17. The method of claim 12 wherein depositing the second tungsten layer comprises depositing tungsten by chemical vapor deposition from tungsten hexafluoride and hydrogen (H₂) at a patterned substrate temperature in excess of 200° C.

18. The method of claim 12 wherein a pressure within the substrate processing region is between about 0.01 Torr and about 50 Torr during the partial etching step.

19. The method of claim 12 wherein forming a plasma in the remote plasma region to produce plasma effluents comprises applying RF power between about 40 watts and about 5000 watts to the remote plasma region.
